(19) United States
(12) Patent Application Publication
(10) Pub. No.: US 2024/0110984 A1
(43) Pub. Date: Apr. 4, 2024

(54) ADVANCED FUSION OF PHYSICS-BASED AND MACHINE LEARNING BASED STATE-OF-CHARGE AND STATE-OF-HEALTH MODELS IN BATTERY MANAGEMENT SYSTEMS

(71) Applicant: Enevate Corporation, Irvine, CA (US)

(72) Inventors: Benjamin Yong Park, Irvine, CA (US); Samuel Keene, Irvine, CA (US); Samer Saab, Irvine, CA (US)

(21) Appl. No.: 17/955,952

(22) Filed: Sep. 29, 2022

(51) Int. Cl. G01R 31/36; G01R 31/367; G01R 31/387; G01R 31/392; G01R 31/396

(52) U.S. Cl. CPC G01R 31/3648; G01R 31/367; G01R 31/387; G01R 31/392; G01R 31/396

(57) ABSTRACT

Systems and methods are provided for advanced fusion of physics-based and machine learning based state-of-charge and state-of-health models in battery management systems.

### TECHNICAL FIELD

Aspects of the present disclosure relate to energy generation and storage. More specifically, certain implementations of the present disclosure relate to methods and systems for advanced fusion of physics-based and machine learning based state-of-charge and state-of-health models in battery management systems.

### BACKGROUND

Various issues may exist with conventional battery technologies. In this regard, conventional systems and methods, if any existed, for designing and producing batteries or components thereof may be costly, cumbersome, and/or inefficient—e.g., they may be complex and/or time consuming to implement, and may limit battery lifetime. In addition, recalls and warranty issues may be costly for products using batteries such as electric vehicles.

Further limitations and disadvantages of conventional and traditional approaches will become apparent to one of skill in the art, through comparison of such systems with some aspects of the present disclosure as set forth in the remainder of the present application with reference to the drawings.

### BRIEF SUMMARY

System and methods are provided for advanced fusion of physics-based and machine learning based state-of-charge and state-of-health models in battery management systems, substantially as shown in and/or described in connection with at least one of the figures, as set forth more completely in the claims.

These and other advantages, aspects and novel features of the present disclosure, as well as details of an illustrated embodiment thereof, will be more fully understood from the following description and drawings.

### BRIEF DESCRIPTION OF THE DRAWINGS

FIG. 1A illustrates an example battery.

FIG. 1B illustrates an example battery management system (BMS) for use in managing operation of batteries.

FIG. 2 is a flow diagram of an example lamination process for forming a silicon-containing or a silicon-dominant cell.

FIG. 3 is a flow diagram of a direct coating process for forming a silicon-containing or a silicon-dominant cell.

FIG. 4 is block diagram illustrating fusing of multiple models, in accordance with the present disclosure.

FIG. 5 is a plot diagram illustrating performance of machine-learning (ML) state-of-charge (SOC) model in accordance with the present disclosure.

FIG. 6 is a plot diagram illustrating performance of physics-based state-of-charge (SOC) model in accordance with the present disclosure.

FIG. 7 is a plot diagram illustrating performance of fused machine-learning (ML) state-of-charge (SOC) models in accordance with the present disclosure.

FIG. 8 is a plot diagram illustrating performance of a fused physics-based and machine learning based state-of-charge (SOC) model in accordance with the present disclosure.

FIG. 9 is a plot diagram illustrating performance of a machine-learning (ML) state-of-health (SOH) model in accordance with the present disclosure.

FIG. 10 is a plot diagram illustrating the difference in SOC prediction performance when using a plain conventional one-time constant Thevenin equivalent circuit model versus a one-time constant Thevenin equivalent circuit model equipped with momentum and overshoot attenuation.

### DETAILED DESCRIPTION

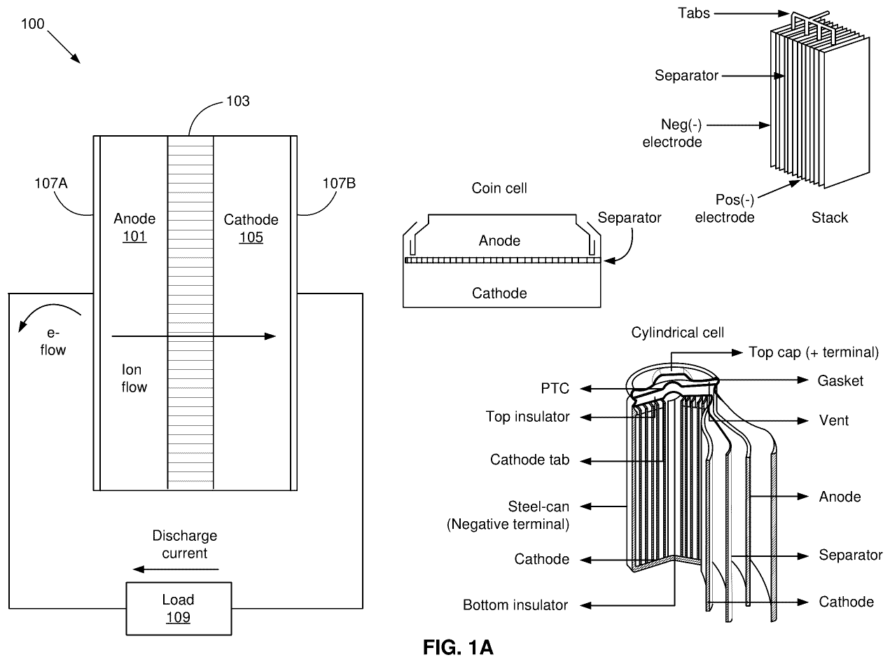

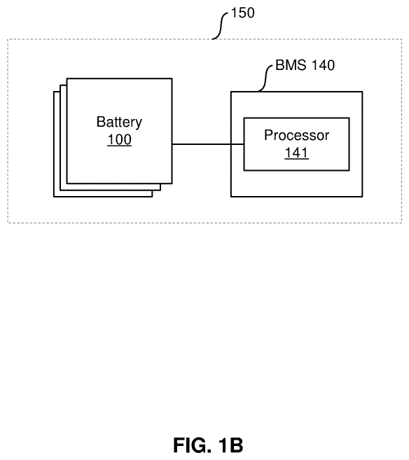

FIG. 1A illustrates an example battery. Referring to FIG. 1A, there is shown a battery 100 comprising a separator 103 sandwiched between an anode 101 and a cathode 105, with current collectors 107A and 107B. There is also shown a load 109 coupled to the battery 100 illustrating instances when the battery 100 is in discharge mode. In this disclosure, the term “battery” may be used to indicate a single electrochemical cell, a plurality of electrochemical cells formed into a module, and/or a plurality of modules formed into a pack. Furthermore, the battery 100 shown in FIG. 1A is a very simplified example merely to show the principle of operation of a lithium-ion cell. Examples of realistic structures are shown to the right in FIG. 1A, where stacks of electrodes and separators are utilized, with electrode coatings typically on both sides of the current collectors except, in certain cases, the outermost electrodes. The stacks may be formed into different shapes, such as a coin cell, cylindrical cell, prismatic pouch cell, or prismatic metal can cell, for example.

The development of portable electronic devices and electrification of transportation drive the need for high-performance electrochemical energy storage. In devices ranging from small-scale (<100 Wh) to large-scale (>10 kWh), Li ion batteries are widely used over other rechargeable battery chemistries due to their advantages in energy density and cyclability.

The anode 101 and cathode 105, along with the current collectors 107A and 107B, may comprise the electrodes, which may comprise plates or films within, or containing, an electrolyte material, where the plates may provide a physical barrier for containing the electrolyte as well as a conductive contact to external structures. In other embodiments, the anode/cathode plates are immersed in electrolyte while an outer casing provides electrolyte containment. The anode 101 and cathode 105 are electrically coupled to the current collectors 107A and 107B, which comprise metal or other conductive material for providing electrical contact to the electrodes as well as physical support for the active material in forming electrodes.

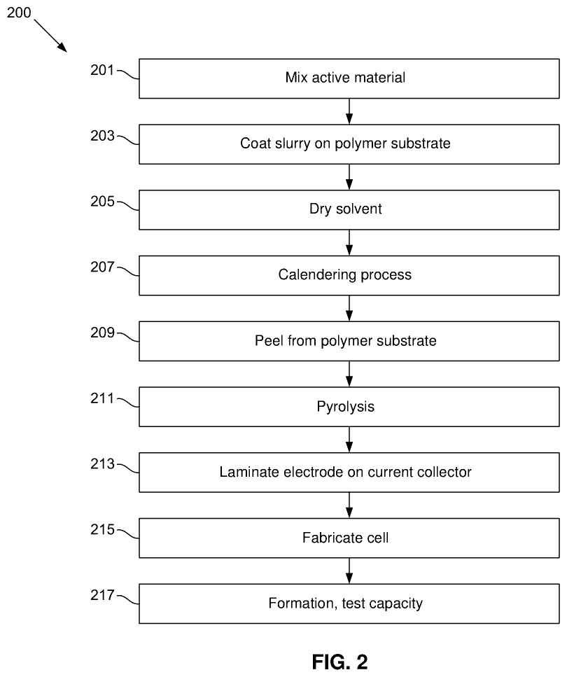

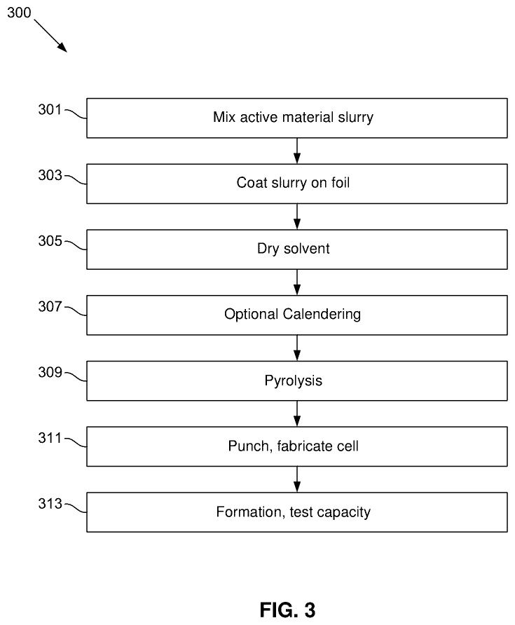

The configuration shown in FIG. 1A illustrates the battery 100 in discharge mode, whereas in a charging configuration, the load 109 may be replaced with a charger to reverse the process. In one class of batteries, the separator 103 is generally a film material, made of an electrically insulating polymer, for example, that prevents electrons from flowing from anode 101 to cathode 105, or vice versa, while being porous enough to allow ions to pass through the separator 103. Typically, the separator 103, cathode 105, and anode 101 materials are individually formed into sheets, films, or active material coated foils. In this regard, different methods or processes may be used in forming electrodes, particularly silicon-containing and/or silicon-dominant (>50% in terms of active material by capacity or by weight) anodes. For example, lamination or direct coating may be used in forming a silicon-containing anode (silicon anode). Examples of such processes are illustrated in and described with respect to FIGS. 2 and 3. Sheets of the cathode, separator and anode are subsequently stacked or rolled with the separator 103 separating the cathode 105 and anode 101 to form the battery 100. In some embodiments, the separator 103 is a sheet and generally utilizes winding methods and stacking in its manufacture. In these methods, the anodes, cathodes, and current collectors (e.g., electrodes) may comprise films.

In an example scenario, the battery 100 may comprise a solid, liquid, or gel electrolyte. The separator 103 preferably does not dissolve in typical battery electrolytes such as compositions that may comprise: Ethylene Carbonate (EC), Fluoroethylene Carbonate (FEC), Propylene Carbonate (PC), Dimethyl Carbonate (DMC), Ethyl Methyl Carbonate (EMC), Diethyl Carbonate (DEC), etc. with dissolved LiBF₄, LiAsF₆, LiPF₆, and LiClO₄, LiFSI, LiTFSI, etc. In an example scenario, the electrolyte may comprise Lithium hexafluorophosphate (LiPF₆) and lithium bis(trifluoromethanesulfonyl)imide (LiTFSI) that may be used together in a variety of electrolyte solvents. Lithium hexafluorophosphate (LiPF₆) may be present at a concentration of about 0.1 to 4.0 molar (M) and lithium bis(trifluoromethanesulfonyl)imide (LiTFSI) may be present at a concentration of about 0 to 4.0 molar (M). Solvents may comprise one or more cyclic carbonates, such as ethylene carbonate (EC), fluoroethylene carbonate (FEC), or propylene carbonate (PC) as well as linear carbonates, such as ethyl methyl carbonate (EMC), diethyl carbonate (DEC), and dimethyl carbonate (DMC), in various percentages. In some embodiments, the electrolyte solvents may comprise one or more of EC from about 0-40%, FEC from about 2-40% and/or EMC from about 50-70% by weight.

The separator 103 may be soaked with a liquid or gel electrolyte. In addition, in an example embodiment, the separator 103 does not melt below about 100 to 140° C., and exhibits sufficient mechanical properties for battery applications. A battery, in operation, can experience expansion and contraction of the anode 101 and/or the cathode 105. In an example embodiment, the separator 103 can expand and contract by at least about 5 to 10% without tearing or otherwise failing, and may also be flexible.

The separator 103 may be sufficiently porous so that ions can pass through the separator once wet with, for example, a liquid or gel electrolyte. Alternatively (or additionally), the separator may absorb the electrolyte through a gelling or other process even without significant porosity. The porosity of the separator 103 is also generally not too porous to allow the anode 101 and cathode 105 to transfer electrons through the separator 103.

The anode 101 and cathode 105 comprise electrodes for the battery 100, providing electrical connections to the device for transfer of electrical charge in charge and discharge states. The anode 101 may comprise silicon, carbon, or combinations of these materials, for example. Typical anode electrodes comprise a carbon material and a current collector, such as a copper sheet. Carbon is often used because it has excellent electrochemical properties and is also electrically conductive. Anode electrodes currently used in rechargeable lithium-ion cells typically have a specific capacity of approximately 200 milliamp hours per gram (mAh/g). Graphite, the active material used in most lithium-ion battery anodes, has a theoretical energy density of 372 mAh/g. In comparison, silicon has a high theoretical capacity of 4200 mAh/g. In order to increase volumetric and gravimetric energy density of lithium-ion batteries, silicon may be used as the active material for the cathode 105 or anode 101. Si anodes may be in the form of a composite on a current collector, with >50% Si by capacity or weight in the composite layer.

In an example scenario, the anode 101 and cathode 105 store the ions used for separation of charge, such as lithium ions. In this example, the electrolyte carries positively charged lithium ions from the anode 101 to the cathode 105 in discharge mode, as shown in FIG. 1A, and vice versa through the separator 103 in charge mode. The movement of the lithium ions and reactions with the electrodes create free electrons in one electrode which creates a charge at the opposite current collector. The electrical current then flows from the current collector where charge is created through the load 109 to the other current collector. The separator 103 blocks the flow of electrons inside the battery 100, allows the flow of lithium ions, and prevents direct contact between the electrodes.

While the battery 100 is discharging and providing an electric current, the anode 101 releases lithium ions to the cathode 105 through the separator 103, generating a flow of electrons from one side to the other via the coupled load 109. When the battery is being charged, the opposite happens where lithium ions are released by the cathode 105 and received by the anode 101.

The materials selected for the anode 101 and cathode 105 are important for the reliability and energy density possible for the battery 100. The energy, power, cost, and safety of current Li-ion batteries need to be improved in order to, for example, compete with internal combustion engine (ICE) technology and allow for the widespread adoption of electric vehicles (EVs). High energy density and high power density of lithium-ion batteries are achieved with the development of high-capacity and high-voltage cathodes, high-capacity anodes and electrolytes with high voltage stability and interfacial compatibility with electrodes. Functionally non-flammable or less-flammable electrolytes could be used to improve safety. In addition, materials with low toxicity are beneficial as battery materials to reduce process cost and promote consumer safety.

The performance of electrochemical electrodes, while dependent on many factors, is largely dependent on the robustness of electrical contact between electrode particles, as well as between the current collector and the electrode particles. The electrical conductivity of silicon anode electrodes may be improved by incorporating conductive additives with different morphological properties. Carbon black (Super P), vapor grown carbon fibers (VGCF), and a mixture of the two have previously been incorporated into the anode to improve electrical conductivity and otherwise improve performance. The synergistic interactions between the two carbon materials may facilitate electrical contact throughout the large volume changes of the silicon anode during charge and discharge as well as provide additional mechanical robustness to the electrode and provide mechanical strength (e.g., to keep the electrode material in place). These contact points (especially when utilizing high-aspect-ratio conductive materials) facilitate the electrical contact between anode material and current collector to mitigate the isolation (island formation) of the electrode material while also improving conductivity in between silicon regions. Graphenes and carbon nanotubes may be used because they may show similar benefits. Thus, in some instances, a mixture of two or more of carbon black, vapor grown carbon fibers, graphene, and carbon nanotubes may be used independently or in combinations for the benefits of conductivity and other performance.

State-of-the-art lithium-ion batteries typically employ a graphite-dominant anode which is a lithium intercalation type anode. Silicon-containing and especially silicon-dominant anodes, however, offer improvements compared to graphite-dominant Li-ion batteries. Silicon exhibits both higher gravimetric (4200 mAh/g vs. 372 mAh/g for graphite) and volumetric capacities (2194 mAh/L vs. 890 mAh/L for graphite). In addition, Si has a higher redox reaction potential versus Li compared to graphite, with a voltage plateau at about 0.3-0.4V vs. Li/Li+, which allows it to maintain an open circuit potential that avoids undesirable Li plating and dendrite formation. While silicon shows excellent electrochemical activity, achieving a stable cycle life for silicon-based anodes is challenging due to silicon's large volume changes during lithiation and delithiation. Silicon regions may lose electrical contact from the anode as large volume changes coupled with its low electrical conductivity separate the silicon from surrounding materials in the anode.

In addition, the large silicon volume changes exacerbate solid electrolyte interphase (SEI) formation, which can further lead to electrical isolation and, thus, capacity loss. Expansion and shrinkage of silicon particles upon charge-discharge cycling causes pulverization of silicon particles, which increases their specific surface area. As the silicon surface area changes and increases during cycling, SEI repeatedly breaks apart and reforms. The SEI thus continually builds up around the pulverizing silicon regions during cycling into a thick electronic and ionic insulating layer. This accumulating SEI increases the impedance of the electrode and reduces the electrode electrochemical reactivity, which is detrimental to cycle life. Therefore, silicon anodes require a strong conductive matrix that (a) holds silicon particles together in the anode, (b) is flexible enough to accommodate the large volume expansion and contraction of silicon, and (c) allows a fast conduction of electrons within the matrix.

Therefore, there is a trade-off among the functions of active materials, conductive additives and polymer binders. The balance may be adversely impacted by high energy density silicon anodes with low conductivity and huge volume variations described above. Polymer binder(s) may be pyrolyzed to create a pyrolytic carbon matrix with embedded silicon particles. In addition, the polymers may be selected from polymers that are completely or partially soluble in water or other environmentally benign solvents or mixtures and combinations thereof. Polymer suspensions of materials that are non-soluble in water could also be utilized.

In addition to the above properties, batteries containing silicon exhibit more hysteresis compared to more common chemistries. This mismatch between the voltage and the actual state of the cell creates difficulties in measuring SOC or SOH. Other chemistries such as lithium iron phosphate (LFP) chemistries also show challenges in determining SOC due to the voltage profile having a large flat portion.

In some embodiments, dedicated systems and/or software may be used to control and manage batteries or packs thereof. In this regard, such dedicated systems may comprise suitable circuitry for running and/or executing control and manage related functions or operations. Further, such software may run on suitable circuitry, such as on processing circuitry (e.g., general processing units) already present in the systems or it may be implemented on dedicated hardware. For example, battery packs (e.g., those used in electric vehicles) may be equipped with a battery management system (BMS) for managing the batteries (or packs) and operations. An example battery management system (BMS) is illustrated in and described in more detail with respect to FIG. 1B.

In accordance with the present disclosure, control and management of batteries, particularly lithium-ion batteries with silicon-containing and, more so, silicon-dominant anodes (also referred to herein as “Si/Li batteries” or “Si—Li batteries”), and operation thereof may be improved, particularly by use of advanced fusion of physics-based and machine learning based state-of-charge (SOC) and state-of-health (SOH) models. Cells with flat profiles such as LFP chemistries will also benefit greatly from the use of these advanced models. In this regard, as noted above battery control and management systems (e.g., BMS) may be used to control and manage the operation of a battery, or a battery pack that may be made up of multiple cells, so as to maximize the useful life of the batteries or packs thereof, to operate the batteries or packs thereof within safety limits, to maintain operational specifications (e.g., minimum power, charge rate, etc.) required for the operation of the batteries or packs thereof, and the like.

Such controlling and managing may depend on and/or entail use of various inputs and parameters. For example, SOH and/or SOC may be used in battery control and management systems (e.g., BMS) to control and manage the operation of a battery, or a battery pack. In this regard, the SOH of a battery (or pack of batteries) may be assessed based on one or more specific considerations or metrics, such as, for example, remaining useful life, possibility or closeness to failure, etc. In implementations with battery packs having multiple cells, the BMS may use calculated SOH of individual cells, groups of cells, or the module or pack as a whole.

The SOC may typically represent level(s) of charge of a battery (or particular cell, or set of cells in a battery pack) relative to its capacity, with SOC values representing charge-based percentage points (e.g., 0.0 or 0%=empty; 1.0 or 100%=full). Controlling and managing batteries (or battery packs) based on SOC may comprise performing SOC based balancing. In particular, in instances where a battery pack comprises multiple cells, the cells may be arranged in parallel, in series, or in combination of both—e.g., with subsets of cells arranged in parallel (or in series), and with each subset comprising a number of cells arranged in series (or in parallel). To ensure optimal performance, it may be desirable that the cells be balanced based on, e.g., SOC thereof. For example, the BMS may routinely calculate the SOC of cells in a battery pack, and based on the calculated SOC, the BMS may control and manage the battery pack—e.g., adjusting the current supplied to individual cells in order to maintain the same voltage or SOC across all of the cells in the battery pack. The calculation of the SOC may be performed if the functional dependence is known, because voltage, current, temperature, and impedance are all measurable quantities. In conventional solutions voltage often may be used as the main indicator of SOC. In this regard, in a battery, a cell's voltage is a function of such parameters and/or factors as applied current, cell impedance, cell temperature, and SOC.

Conventional solutions that use SOC and/or SOH may have some limitations and/or issues, however, particularly when used with particular types of batteries such as Si/Li batteries. In this regard, state-of-charge (SOC) and state-of-health (SOH) balancing in battery management systems (e.g., BMS) may be dependent on advanced SOC and SOH models. Traditional SOC and SOH models, however, may fail to model Si/Li batteries due to several reasons, such as voltage hysteresis, shifting electrode voltages, different fade mechanisms, and the volume changes of the Si anode during charging and discharging. Use of such models may greatly benefit from an approach that combines two or more of any of the physics-based and machine learning (ML) models. Moreover, use of existing models may be constrained to only the present context or environment affecting the immediate operation of the battery pack. Thus, the models may lack forecasting capabilities which may be used to adjust voltage limits of the packs before the battery enters a new operational state (e.g., predicted large temperature drop or surge).

In various implementations based on the present disclosure, control and management of batteries may be improved by use of advanced or enhanced modeling techniques, particularly by use of multiple SOC and/or SOH models, and advanced fusion thereof, with these models being of different types, such as physics-based and machine learning (ML) based models. Examples of such implementation and/or details relating to various features associated therewith are described in more details below.

FIG. 1B illustrates an example battery management system (BMS) for use in managing operation of batteries. Shown in FIG. 1B is battery management system (BMS) 140.

The battery management system (BMS) 140 may comprise suitable circuitry (e.g., processor 141) configured to manage one or more batteries (e.g., each being an instance of the battery 100 as described with respect with FIG. 1A). In this regard, the BMS 140 may be in communication and/or coupled with each battery 100. In some implementations, a separate processor (e.g., a conventional processor, such as an electronic control unit (ECU), a microcontroller unit (MCU), or the like), or several such separate processors, may be used, and may be configured to handle algorithms or control functions with regards to the batteries. In such implementations, such processor(s) may be connected to the batteries, such as through the processor 141, and thus may be treated as part of the BMS 140 and acting as part of processor 141.

In some embodiments, the battery 100 and the BMS 140 may be in communication and/or coupled with each other, for example, via electronics or wireless communication. In some embodiments, the BMS 140 may be incorporated into the battery 100. Alternatively, in some embodiments, the BMS 140 and the battery 100 may be combined into a common package 150. Further, in some embodiments, the BMS 140 and the battery 100 may be separate devices/components, and may only be in communication with one another when present in the same system. The disclosure is not limited to any particular arrangement, however.

In accordance with the present disclosure, control and management of batteries, particularly Si/Li batteries or LFP batteries, and operation thereof may be improved, particularly by use of advanced fusion of physics-based and machine learning based state-of-charge (SOC) and state-of-health (SOH) models. In this regard, battery control and management systems, such as the BMS 140 of FIG. 1B, may be configured to support and facilitate use of fusing of multiple SOC and/or SOH models as described herein. In this regard, as noted above, battery control and management systems, such as the BMS 140, may be used to control the operation of a battery (or a battery pack, which may be made up of multiple cells), so as to maximize the useful life of the battery (or a battery pack), to operate the battery (or a battery pack) within safety limits, to maintain required operational specifications (e.g., minimum power, charge rate), and the like. Use of SOC and/or SOH models may have some limitations, however. The present disclosure addresses such limitations, particularly by use of advance model fusing, which may comprise fusing multiple SOC and/or SOH models, including models of different types, to account for and/or remedy any shortcoming that may arise from using individual models.

In various example embodiments, the BMS 140 may be configured to control (e.g., set, adjust, or modify) one or more operating parameters (e.g., current) applied to individual batteries, cells, strings of cells, groups of cells that are connected in parallel, or other groups of cells (such as a module) in a battery module or pack, with the SOC and SOH calculated using multiple models. The cells may comprise silicon. In particular, the cells may comprise >50% silicon as the active material. The cells may comprise LFP. The multiple models may be fused to optimize performance.

In an example embodiment, the multiple models may be all machine learning (ML) models.

In an example embodiment, the multiple models may be all physics-based (e.g., equivalent circuit model (ECM)) models.

In an example embodiment, the multiple models may be a combination of machine learning and physics-based (e.g., ECM) models.

In an example embodiment, at least one model may be based on a physical model of the cell. For example, such physical model may be based on combination of pertinent physical phenomena that are modeled as factors that affect the relationship between SOC and cell voltage, current, and temperature. The physical phenomena may comprise, e.g., open circuit voltage (OCV) hysteresis modeled by two different OCV vs. SOC curves (one for charge and one for discharge), OCV hysteresis modeled by differences in thermodynamic pathways for lithiation and delithiation, OCV hysteresis modeled by a correction to the OCV vs. SOC curve based on the mechanical strain in the electrode particles, SOC-dependent impedance, SOC-dependent changes the porosity, particle size, interfacial resistance, and other properties of the microstructure that affect the impedance of the electrode, SOH-dependent changes the porosity, particle size, interfacial resistance, and other properties of the microstructure that affect the impedance of the electrode, or any combination of such physical phenomena.

In an example embodiment, the BMS 140 may be configured to equilibrate or at least modify the state-of-charge (SOC) to be closer to each other (e.g., for multiple cells or groups of cells), ensuring all the cells or groups of cells are at a more uniform SOC, where SOC is defined as the fraction or percent of capacity between the fully discharged state (0% SOC) and the fully charged state (100% SOC).

In an example embodiment, the BMS 140 may be configured to modify and control the operating parameters to equilibrate the state-of-health (SOH) of all the cells in the pack, ensuring all cells are at a uniform SOH.

In an example embodiment, at least one model may be based on a physics-based model that is an equivalent circuit model (ECM) comprising any number of in-series and/or parallel circuit elements which may include, but are not limited to, resistors, capacitors, inductors, etc.

In an example embodiment, the ECM may be designed according to simulated data, collected real data, or may vary during real-time operation as new data comes in. One or more of the circuit elements may be time-varying or functions of relevant phenomena such as temperature or applied current. One or more of the circuit elements may be fine-tuned according to data (simulated, collected, or real-time), or based on electrochemical impedance spectroscopy (EIS) measurements.

In an example embodiment, the ECM may be equipped with a momentum parameter which accumulates an exponentially decaying moving average of past predictions in order to smoothen the predictions. This is used to reduce unrealistic fluctuations in the predictions of the ECM. The momentum may be applied on any of the states within the ECM, including the states representing voltage and/or current across each of the circuit parameters, the open-circuit voltage prediction itself, the SOC prediction itself, and/or even certain inputs such as voltage, current, and/or temperature. Other smoothing algorithms may be applied as well, such as moving average or applying low-pass, band-pass, and/or high-pass filters.

In an example embodiment, the ECM may be equipped with parameters designed to attenuate overshoot predictions in correlation to the time-gradient of certain observations such as current, voltage, and/or temperature. This overshoot prediction may be tailored in accordance to the hysteresis between charge and discharge of the battery being modeled. Thus, this overshoot attenuation may be implemented whenever the state of the battery is switched between charge, discharge, and/or rest, and the scaling factor be a function of the expected hysteresis at the OCV prediction value which may be known a priori from collected OCV vs SOC data.

In an example embodiment, the ECM may be equipped with parameters that either accelerate or decelerate the settling time of certain predictions in order to get accurate open-circuit voltage predictions in scenarios where the applied load fluctuates at high or low rates.

In an example embodiment, the ECM may be designed or configured to use one or more SOC-OCV look-up tables. The SOC-OCV relationship may be collected at various values of SOH and/or temperature.

In an example embodiment, at least one model may be a machine-learning (ML) model trained on data acquired during operation of multiple cells and battery packs. Such ML model may be trained using one or more ML algorithms. Example ML algorithms may comprise linear regression, logistic regression, nonlinear regression, decision tree ensemble methods (such as gradient boosting or random forests), neural networks, recurrent neural networks such as long-short-term memory networks, Gaussian process algorithms, Bayesian algorithms, and graph neutral networks. The model may be trained using any combination of the following data features: voltage, current, temperature, cumulative charge and discharge capacity, curve fits of other quantitative calculations based on portions of voltage profiles, voltage, thickness, and impedance measurements acquired during the manufacture of the cell, features calculated based on sections of the voltage profile of the cell, the change in voltage when the cell transitions from a state with no current applied to a state with current applied, and the complete (or partial) voltage, current, and temperature history of the cell.

In an example embodiment, the ML model may be designed or configured to use probabilistic features that are inherently predictive of a future state. Such features may be collected from a time-window of any desired length that describes the temporal dynamics/behavior of the cells' usage. Such features may originate from the combination of symbolic time-series analysis and either finite state automata or probabilistic finite state automata (PFSA). The construction of the state automata may lead probabilistic state transition matrices formed on local fast time-varying measurements/observations and/or historic slow time varying context-related features (e.g., environmental observations such as weather). The PFSA-based features are taken from battery-related measurements (e.g., voltage, current, and temperature) or other representational drive data (e.g., traffic vs time maps). These features may be used to predict the driver's behavior or sudden temperature changes, which may be used to trigger the BMS to adjust parameters for safety.

In an example embodiment, the ML model may be designed or configured to use “fingerprint” features that distinguish certain modes/styles of battery usage (e.g.; driving) and/or be indicative of certain driver profiles. These fingerprint features may be derived using the probabilistic state transition matrices derived from the applied current on the battery, which allows for features that characterize the driver profile. By comparing the state transition matrices that are derived at numerous time-windows (e.g.; PFSA state transition matrix over the last 1 minute, 10 minutes, 1 hour, and entire history of the battery pack's usage), a metric may thus be created to indicate whether the user (or driver) has changed and/or whether the environment has changed (e.g.; transitioning from a highway to a city).

In an example embodiment, the ML model may be designed or configured to use “fingerprint” features that distinguish certain modes/styles of battery usage (e.g.; driving) and/or be indicative of certain driver profiles. These fingerprint features may be derived through statistical comparisons of battery usage behavior with pre-defined battery usage datasets that may be collected in a lab environment, real battery usage data, and/or publicly available battery usage datasets. These statistical comparisons may be done in numerous ways by first defining a distribution over the battery usage of the pre-collected battery usage datasets and the real-time battery usage data using Bayesian methods, Gaussian methods, kernel-based methods, non-parametric kernel-based methods, adaptive histograms, and other density estimation methods. The comparisons may thus be made using numerous distribution-similarity metrics, such as the Kullback-Leibler (KL) divergence score, Jensen-Shannon divergence score, Kolmogorov-Smirnov score, etc. The score indicating the highest similarity between the real time battery usage data and the pre-defined battery usage datasets indicates the driver mode or driver profile, which may be used to help adjust the selection of which models to employ for enhanced cell-state model predictions.

In an example embodiment, a feedback system may be used. The feedback system may be built around the predictive/forecasting models as described above, and/or based on the SOC and/or SOH models described in this disclosure.

In an example embodiment, at least one model may be semi-empirical—that is, being designed, built or modified based on a mixture of physics and fits to data.

In an example embodiment, the BMS 140 may be configured to determine the SOC or SOH by a combination of the models using non-ML models or methods (e.g., averaging or weighted averaging, stacking, blending, etc.).

In an example embodiment, a combination of models may be fused at the observation level (e.g., synchronization, loose-synchronization, padding, etc. of the sensor measurements), feature level (e.g., concatenation of synchronized heterogeneous sensor measurement features), and/or decision level (e.g., weighted average of models' predictions, selection of output based on confidence levels of every model output, switcher based on a certain observation such as temperature, etc.).

In an example embodiment, a physics-based ECM may be fused with other models, such as using Kalman filter, extended Kalman filter, particle filter, or an extension thereof, to enhance state-estimation within the ECM.

In an example embodiment, parameters in at least one model applicable to one or more cells (or groups of cells) may be based on data acquired in the factory, for instance: cell thickness, cell resistance, cell open-circuit-voltage (OCV), any data related to or acquired during the formation of the cell or fabrication of the cell components.

In an example embodiment, parameters in at least one model applicable to one or more cells (or groups of cells) may be based on, and/or updated using data acquired during the operation of the cell. Such updates may be based on the calculated SOH of the cell, but may also be based on any other calculation.

In an example embodiment, SOC prediction per cell or group of cells for at least one model may be updated based on the deviation between the most recent SOC calculation and SOC measurement. For example, in a scenario where the true SOC of a cell is occasionally measured: on measurement number n, the difference between the measured SOC and the calculated SOC is δ. For subsequent calculations of SOH (until the next measurement), δ is added to the modeled SOC value and this “updated” calculation of SOC is used by the BMS. This procedure is repeated after each measurement of true SOC is made.

In an example embodiment, the BMS 140 may be configured to keep at least some of the cells or groups of cells within 5%, 2%. 1% or 0.5% of a tracked value at any given point in the life of the pack. The tracked value may be the median or average SOC of the cells in the pack.

In an example embodiment, the discharge current applied to cells with SOC lower than the average of the pack may be reduced.

In an example embodiment, the discharge current applied to cells with SOC higher than the average of the pack may be increased.

In an example embodiment, the charge current applied to cells with SOC lower than the average of the pack may be increased.

In an example embodiment, the charge current applied to cells with SOC higher than the average of the pack may be reduced.

In an example embodiment, no current is applied to cells whose SOC is calculated to be above or below a certain threshold, such as, e.g., above 99% or below 1%, above 95% or below 5%, above 90% or below 10%.

In an example embodiment, the fusing of the multiple models may comprise averaging outputs of all (or at least some) of the models.

In an example embodiment, the fusing of the multiple models may comprise averaging outputs of all (or at least some) of the models in a weighted sense—e.g., where more weight is assigned to more reliable models according to prior test-set performances.

In an example embodiment, the fusing of the multiple models may comprise feeding outputs of all (or at least some) into a separate model designed or configured for model fusion. The separate model may be a ML model. Such ML model may be configured to receive input data that each individual model receives along with their outputs.

In an example embodiment, the fusing of the multiple models may comprise use of a switcher that is designed or otherwise configured to select one or more models (e.g., ML models) that may be better trained, such as according to applied load. When more than one model is chosen, the chosen models may be fused as described herein. The switcher may have high resolution ranges (e.g., 0.5 to 0.6 C-rate, 0.6 to 0.7 C-rate, 0.7 to 0.8 C-rate etc.) or lower resolution ranges (e.g., 0 to 2 C-rate, 2 to 4 C-rate, 4 to 6 C-rate, etc.).

In an example embodiment, the switcher may be designed or otherwise configured to select one or more ML models better trained according to current temperature of the battery pack. When more than one model is chosen, the chosen models may be fused as described herein. The switcher may have a resolution as high as sub-centigrade ranges (e.g., 25 C to 25.5 C, 25.5 C to 26 C, 26 C to 26.5 C, etc.) to several centigrade ranges (e.g., 25 C to 30 C, 30 C to 35 C, 35 C to 40 C, etc.).

In an example embodiment, the switcher may be designed or otherwise configured to select one or more ML models better trained according to the current SOH of the cells or total utilized capacity. When more than one model is chosen, the chosen models may be fused as described herein. The switcher may have high resolution ranges (e.g., 0.5 to 0.6 Ah, 0.6 to 0.7 Ah, 0.7 to 0.8 Ah etc.) or lower resolution ranges (e.g., 0 to 10 Ah, 10 to 20 Ah, 20 to 30 Ah, etc.).

In an example embodiment, the switcher may be designed or otherwise configured to select one or more ML models better trained according to the determined driving mode or driver profile as indicated by the fingerprint features based on the probabilistic state transition matrices.

In an example embodiment, the switcher may be designed or otherwise configured to select one or more ML models better trained according to the determined driving mode or driver profile as indicated by the fingerprint features based on similarity scores of real-time battery usage data distribution and pre-defined battery usage dataset distributions.

In an example embodiment, the switcher may be designed or otherwise configured to select one or more physics-based models better tuned according to the applied load. When more than one model is chosen, the chosen models may be fused as described herein. The switcher may have high resolution ranges (e.g., 0.5 to 0.6 C-rate, 0.6 to 0.7 C-rate, 0.7 to 0.8 C-rate etc.) or lower resolution ranges (e.g., 0 to 2 C-rate, 2 to 4 C-rate, 4 to 6 C-rate, etc.).

In an example embodiment, the switcher may be designed or otherwise configured to select one or more physics-based models better tuned according to current temperature of the battery pack. When more than one model is chosen, the chosen models may be fused as described herein. The switcher may have a resolution as high as sub-centigrade ranges (e.g., 25 C to 25.5 C, 25.5 C to 26 C, 26 C to 26.5 C, etc.) to several centigrade ranges (e.g., 25 C to 30 C, 30 C to 35 C, 35 C to 40 C, etc.).

In an example embodiment, the switcher may be designed or otherwise configured to one or more physics-based models better tuned according to the current SOH of the cells or total utilized capacity. When more than one model is chosen, the chosen models may be fused as described herein. The switcher may have high resolution ranges (e.g., 0.5 to 0.6 Ah, 0.6 to 0.7 Ah, 0.7 to 0.8 Ah etc.) Or lower resolution ranges (e.g., 0 to 10 Ah, 10 to 20 Ah, 20 to 30 Ah, etc.).

In an example embodiment, the switcher may be designed or otherwise configured to select one or more physics-based models better trained according to the determined driving mode or driver profile as indicated by the fingerprint features based on the probabilistic state transition matrices.

In an example embodiment, the switcher may be designed or otherwise configured to select one or more physics-based models better trained according to the determined driving mode or driver profile as indicated by the fingerprint features based on similarity scores of real-time battery usage data distribution and pre-defined battery usage dataset distributions.

In an example embodiment, the switcher may be designed or otherwise configured to select multiple physics-based and ML-based models, such as according to any of the metrics as described herein. The selected models may be fused as described herein.

In an example embodiment, the switcher may be designed or otherwise configured to depend on or otherwise use any other battery-related measurements, traffic-related observations, or driver-related information. Such switchers may operate at various resolutions according to the chosen measurements, observations, or information.

The implementation of advanced SOC and SOH models in battery control and management systems, such as the BMS 140, may enable safer operation of the battery (or battery pack). The models described herein may allow for merging various physics-based and machine-learning based models, which offers higher confidence in the model predictions. Physics-based models ensure that the predictions are physically informed and mitigates the possibility of un-explainable outlier predictions, while the ML models offer higher representational power dependent on the quality of the training dataset. Furthermore, additional forecasting capabilities may enable the BMS to manipulate voltage limits for the safety and longevity of the cells. The surrounding contexts of the battery packs may be time-varying and at different rates, which may greatly affect the cells. Traffic patterns, which informs the model of an expected usage behavior, or sudden temperature changes are examples of differently varying contexts that may be used for enhanced BMS operation.

In some instances, at least some of the models described herein may be validated, such as on datasets derived from publicly available standardized drive-cycle data. Three drive-cycles are used for the validation, one is taken from the Worldwide harmonized Light vehicles Test Procedures (WLTP), and two from the Federal Test Procedures (FTP), specifically US06 procedure and FTP-75 procedure. The US06 was developed to reflect aggressive, high speed, and high acceleration driving behavior. The US06 cycle represents an 8.01-mile route with an average speed of 48.4 mph, maximum speed of 80.3 mph, maximum acceleration rate of 8.46 mph/sec, and duration of 596 seconds. The FTP-75 has a total distance travelled of 11.04 miles, an average speed of 21.2 miles per hour (mph), and a total duration of 1874 seconds. The way in which the data was used was by converting the publicly available data into power time-series data, which is then fed into a cycler in a lab setting. A single drive-cycle is taken by repeating the power time-series data until lower cut-off voltages or random depths of discharge (DOD) are reached. The cycles are implemented at various temperatures, which may be static throughout the entire experiment or randomly time-varying.

FIG. 2 is a flow diagram of an example lamination process for forming a silicon-containing or a silicon-dominant cell. This process employs a high-temperature pyrolysis process on a substrate, layer removal, and a lamination process to adhere the active material layer to a current collector. This strategy may also be adopted by other types of anodes, such as graphite, conversion type anodes, such as transition metal oxides, transition metal phosphides, and other alloy type anodes, such as Sn, Sb, Al, P, etc.

To fabricate an anode, the raw electrode active material is mixed in step 201. In the mixing process, the active material may be mixed with a binder/resin (such as water soluble PI (polyimide), PAI (polyamideimide), carboxymethyl cellulose (CMC), styrene-butadiene rubber (SBR), poly(acrylic acid) (PAA), Sodium Alginate, Phenolic or other water soluble resins and mixtures and combinations thereof), solvent, rheology modifiers, surfactants, pH modifiers, and conductive additives. The materials may comprise carbon nanotubes/fibers, graphene sheets, metal polymers, metals, semiconductors, and/or metal oxides, for example. Silicon powder with a 1-30 or 5-30 μm particle size, for example, may then be dispersed in polyamic acid resin, PAI, or PI (15-25% solids in N-Methyl pyrrolidone (NMP) or deionized (DI) water) at, e.g., 1000 rpm for, e.g., 10 minutes, and then the conjugated carbon/solvent slurry may be added and dispersed at, e.g., 2000 rpm for, e.g., 10 minutes to achieve a slurry viscosity within 2000-4000 cP and a total solid content of about 30-40%. The pH of the slurry can be varied from acidic to basic, which may be beneficial for controlling the solubility, conformation, or adhesion behavior of water soluble polyelectrolytes, such as polyamic acid, carboxymethyl cellulose, or polyacrylic acid. Ionic or non-ionic surfactants may be added to facilitate the wetting of the insoluble components of the slurry or the substrates used for coating processes. The particle size and mixing times may be varied to configure the electrode coating layer density and/or roughness.

Furthermore, cathode electrode coating layers may be mixed in step 201, and coated (e.g., onto aluminum), where the electrode coating layer may comprise cathode material mixed with carbon precursor and additive as described above for the anode electrode coating layer. The cathode material may comprise Lithium Nickel Cobalt Manganese Oxide (NMC (also called NCM): LiNiₓCo_{y}Mn_{z}O₂, x+y+z=1), Lithium Iron Phosphate (LFP: LiFePO₄/C), Lithium Nickel Manganese Spinel (LNMO: e.g. LiNi_{0.5}Mn_{1.5}O₄), Lithium Nickel Cobalt Aluminum Oxide (NCA: LiNiₐCo_{b}Al_{c}O₂, a+b+c=1), Lithium Manganese Oxide (LMO: e.g. LiMn₂O₄), a quaternary system of Lithium Nickel Cobalt Manganese Aluminum Oxide (NCMA: e.g. Li[Ni_{0.89}Co_{0.05}Mn_{0.05}Al_{0.01}]O₂, Lithium Cobalt Oxide (LCO: e.g. LiCoO₂), and other Li-rich layer cathodes or similar materials, or combinations thereof. The particle size and mixing times may be varied to configure the electrode coating layer density and/or roughness.

In step 203, the slurry may be coated on a substrate. In this step, the slurry may be coated onto a polyester, polyethylene terephthalate (PET), or Mylar film at a loading of, e.g., 2-4 mg/cm 2 and then undergo drying in step 205 to an anode coupon with high Si content and less than 15% residual solvent content. This may be followed by an optional calendering process in step 207, where a series of hard pressure rollers may be used to finish the film/substrate into a smoothed and denser sheet of material.

In step 209, the active-material-containing film may then be removed from the PET, where the active material layer may be peeled off the polymer substrate. The peeling may be followed by a pyrolysis step 211 where the material may be heated to, e.g., 600-1250° C. for 1-3 hours, cut into sheets, and vacuum dried using a two-stage process (120° C. for 15 h, 220° C. for 5 h). The peeling process may be skipped if polypropylene (PP) substrate is used, and PP can leave ˜2% char residue upon pyrolysis.

In step 213, the electrode material may be laminated on a current collector. For example, a 5-20 μm thick copper foil may be coated with polyamide-imide with a nominal loading of, e.g., 0.2-0.6 mg/cm 2 (applied as a 6 wt % varnish in NMP and dried for, e.g., 12-18 hours at, e.g., 110° C. under vacuum). The anode coupon may then be laminated on this adhesive-coated current collector. In an example scenario, the silicon-carbon composite film is laminated to the coated copper using a heated hydraulic press. An example lamination press process comprises 30-70 seconds at 300° C. and 3000-5000 psi, thereby forming the finished silicon-composite electrode.

In step 215, the cell may be formed. In this regard, the anode may be used to assemble a cell with cathode, separator and electrolyte materials. In some instances, separator with significant adhesive properties may be utilized.

In step 217, the cell may be assessed before being subject to a formation process. The measurements may comprise impedance values, open circuit voltage, and electrode and cell thickness measurements. The formation cycles are defined as any type of charge/discharge of the cell that is performed to prepare the cell for general cycling and is considered part of the cell production process. Different rates of charge and discharge may be utilized in formation steps. During formation, the initial lithiation of the anode may be performed, followed by delithiation. Cells may be clamped during formation and/or cycling.

FIG. 3 is a flow diagram of a direct coating process for forming a silicon-containing or a silicon-dominant cell. This process comprises physically mixing the active material, conductive additive, and binder together, and coating the mixed slurry directly on a current collector before pyrolysis. This example process comprises a direct coating process in which an anode or cathode slurry is directly coated on a copper foil using a binder such as CMC, SBR, PAA, Sodium Alginate, PAI, PI and mixtures and combinations thereof.

In step 301, the active material may be mixed with, e.g., a binder/resin (such as PI, PAI or phenolic), solvent (such as NMP, water, other environmentally benign solvents or their mixtures and combinations thereof), and conductive additives. The materials may comprise carbon nanotubes/fibers, graphene sheets, metal polymers, metals, semiconductors, and/or metal oxides, for example. Silicon powder with a 1-30 μm particle size, for example, may then be dispersed in polyamic acid resin, PAI, PI (15% solids in DI water or N-Methyl pyrrolidone (NMP)) at, e.g., 1000 rpm for, e.g., 10 minutes, and then the conjugated carbon/solvent slurry may be added and dispersed at, e.g., 2000 rpm for, e.g., 10 minutes to achieve a slurry viscosity within 2000-4000 cP and a total solid content of about 30-40%.

Furthermore, cathode active materials may be mixed in step 301, where the active material may comprise lithium cobalt oxide (LCO), lithium iron phosphate, lithium nickel cobalt manganese oxide (NMC), lithium nickel cobalt aluminum oxide (NCA), lithium manganese oxide (LMO), lithium nickel manganese spinel, or similar materials or combinations thereof, mixed with a binder as described above for the anode active material.

In step 303, the slurry may be coated on a copper foil. In the direct coating process described here, an anode slurry is coated on a current collector with residual solvent followed by a drying and a calendering process for densification. A pyrolysis step (˜500-800° C.) is then applied such that carbon precursors are partially or completely converted into glassy carbon or pyrolytic carbon. Similarly, cathode active materials may be coated on a foil material, such as aluminum, for example. The active material layer may undergo a drying process in step 305 to reduce residual solvent content. An optional calendering process may be utilized in step 307 where a series of hard pressure rollers may be used to finish the film/substrate into a smoother and denser sheet of material. In step 307, the foil and coating optionally proceeds through a roll press for calendering where the surface is smoothed out and the thickness is controlled to be thinner and/or more uniform.

In step 309, the active material may be pyrolyzed by heating to 500-1000° C. such that carbon precursors are partially or completely converted into glassy carbon. Pyrolysis can be done either in roll form or after punching. If the electrode is pyrolyzed in a roll form, it will be punched into individual sheets after pyrolysis. The pyrolysis step may result in an anode active material having silicon content greater than or equal to 50% by capacity or by weight. In an example scenario, the anode active material layer may comprise 20 to 95% silicon. In another example scenario may comprise 50 to 95% silicon by weight.

In step 311, the cell may be formed, which may also include punching the electrode. In this regard, in instances where the current collector foil is not pre-punched/pre-perforated, the formed electrode may be punched. The formed electrode may be perforated with a punching roller, for example. The punched anodes may then be used to assemble a cell with cathode, separator and electrolyte materials. In some instances, separator with significant adhesive properties may be utilized.

In step 313, the cell may be assessed before being subject to a formation process. The measurements may comprise impedance values, open circuit voltage, and cell and/or electrode thickness measurements. During formation, the initial lithiation of the anode may be performed, followed by delithiation. Cells may be clamped during formation and/or early cycling. The formation cycles are defined as any type of charge/discharge of the cell that is performed to prepare the cell for general cycling and is considered part of the cell production process. Different rates of charge and discharge may be utilized in formation steps.

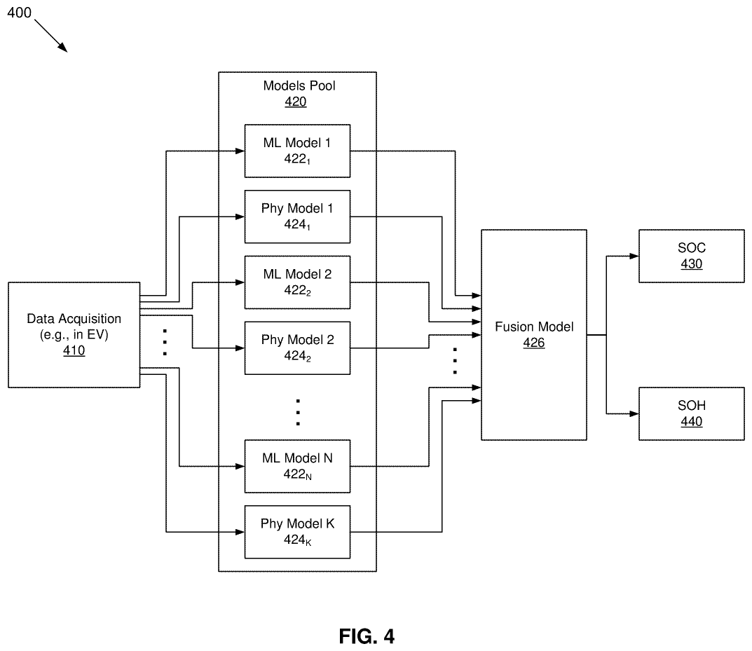

FIG. 4 is block diagram illustrating fusing of multiple models, in accordance with the present disclosure. Shown in FIG. 4 is multiple model fusion arrangement 400.

In this regard, the arrangement 400 may be implemented in a suitable system, particularly a battery control and management system, such as the BMS 140 described with respect to FIG. 1B. Accordingly, the data (or data structures) described with respect to the arrangement 400 may be implemented and/or stored using suitable storage circuitry in the system. Similarly, the processing and/or other handling actions described with respect to the arrangement 400 may be implemented, performed, and/or otherwise handled via suitable processing circuitry in the system. The arrangement 400 may be designed, implemented, and/or configured to support and/or implement multiple model fusion as described herein.

For example, as shown in the example embodiment illustrated in FIG. 4, a models pool 420 may be used, comprising a plurality of models, which may comprise models of different types of models, such as machine-learning (ML) models and physics-based models. In the particular embodiment illustrated in FIG. 4, the models pool 420 comprises one or more machine-learning (ML) models 4221-422N, and one or more physics based models 4241-424K. Thus, there may be different number of models for each of the different types of models.

In some instances, the models may receive input data, which may be acquired, such as via data acquisition (block) 410. The input data may comprise data obtained during manufacturing and/or data obtained during operation and use of the battery (e.g., being implemented via the platform incorporating the battery, such as an electric vehicle (EV)). The data acquisition 410 may be configured to support obtaining and/or providing/feeding various sample rate data.

In operation, multiple models may be fused, such as via fusion model (block) 426. In this regard, model fusing model may comprise combining multiple models, may be of the same or different types. The resultant fusion model may be of a particular type, such as machine-learning (ML) fusion model. The models may be fused at the observation level (e.g., synchronization, loose-synchronization, padding, etc. of the sensor measurements), feature level (e.g., concatenation of synchronized heterogeneous sensor measurement features), and/or decision level (e.g., weighted average of models' predictions, selection of output based on confidence levels of every model output, switcher based on a certain observation such as temperature, etc.). The fusion model may then be used in modeling and/or determining state-of-charge (SOC) 430 and state-of-health (SOH) 440, which in turn are used in controlling and managing batteries (or cells, groups of cells, etc. thereof) and operation thereof.

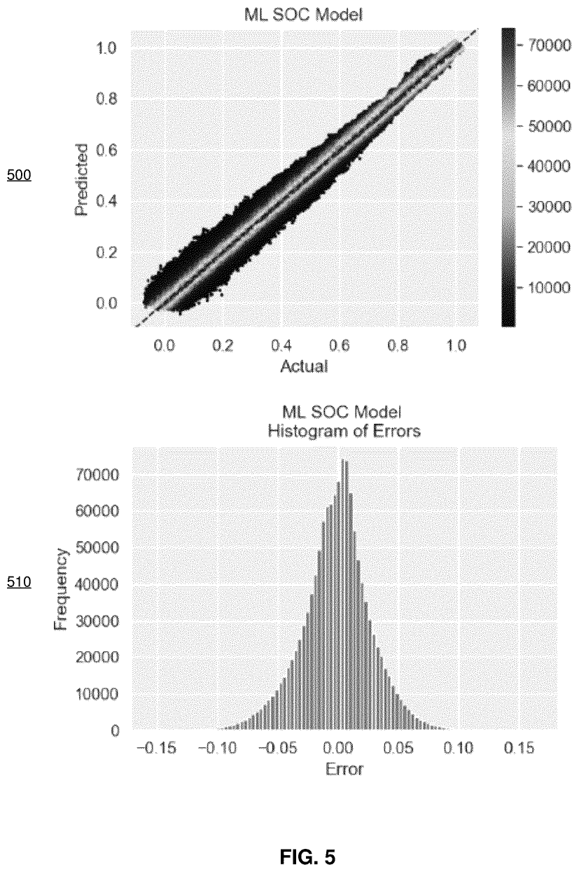

FIG. 5 is a plot diagram illustrating performance of a machine-learning (ML) state-of-charge (SOC) model in accordance with the present disclosure. Shown in FIG. 5 are plots 500 and 510 that illustrate performance of an example ML-based SOC model.

In this regard, plot 500 includes predicted versus measured SOC values, to illustrate performance of the ML-based SOC model. In particular, the y-axis in plot 500 shows the SOC (values) predicted by the ML-based SOC model whereas the x-axis shows the actual SOC (values). Thus, each point in the plot represents the measured and calculated values for a single SOC point from the cycled cells in the dataset. The dashed lines represent instances where the modeled SOC equals the actual SOC. Plot 510 includes the corresponding histogram of error figures of the values in plot 500.

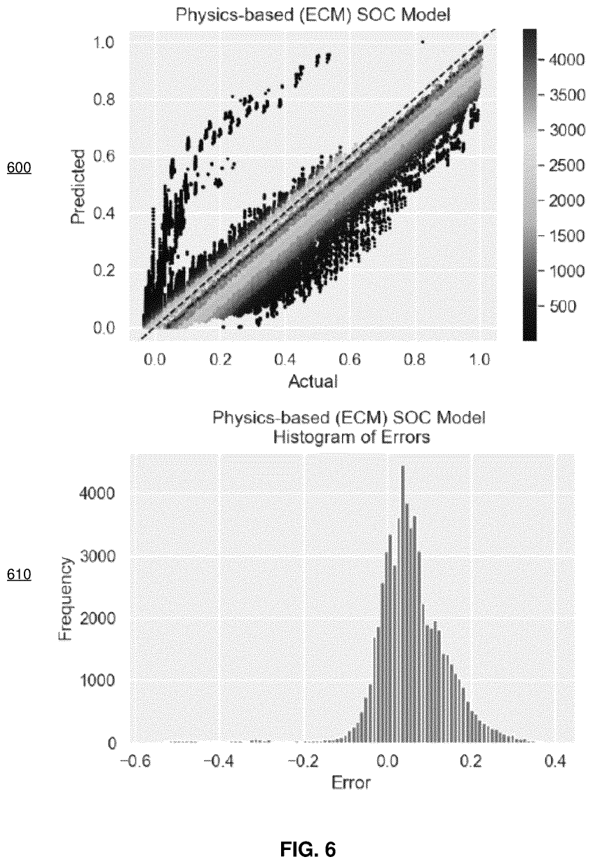

FIG. 6 is a plot diagram illustrating performance of physics-based state-of-charge (SOC) model in accordance with the present disclosure. Shown in FIG. 6 are plots 600 and 610 that illustrate performance of an example ECM-based SOC model.

In this regard, plots 600 and 610 may be similar to the plots 500 and 510—that is, with plot 600 including predicted SOC values (the y-axis) vs. actual SOC values (the x-axis), and plot 610 including the corresponding histogram of error figures of the values in plot 600. The plots 600 and 610 include data points illustrating performance of the example ECM-based SOC model, however.

As illustrated in FIGS. 5 and 6, the predicted versus actual values are color coded in plots 500 and 600 to highlight the number of stacked data points that have the same error value, which may be reflected in the corresponding histogram figures shown in plots 510 and 610. As illustrated in plots 500, 510, 600, and 610 of FIGS. 5 and 6 (that is, the predicted vs. actual figures, along with their corresponding histogram of error figures), use of an ML-based SOC model may yield the enhanced performance over a conventional equivalent circuit model for SOC modeling. For example, the results shown in FIGS. 5 and 6 illustrate that the ML-based SOC model achieves, e.g., a mean absolute error (MAE) of 2.16%, root mean-squared error (RMSE) of 2.86%, and r-squared value of 99.07%; whereas the ECM model achieves, e.g., a MAE of 8.02%, RMSE of 11.08%, and r-squared value of 88.14%. The test dataset includes WLTP at room temperature, with a total number of, e.g., 1,273,762 data points.

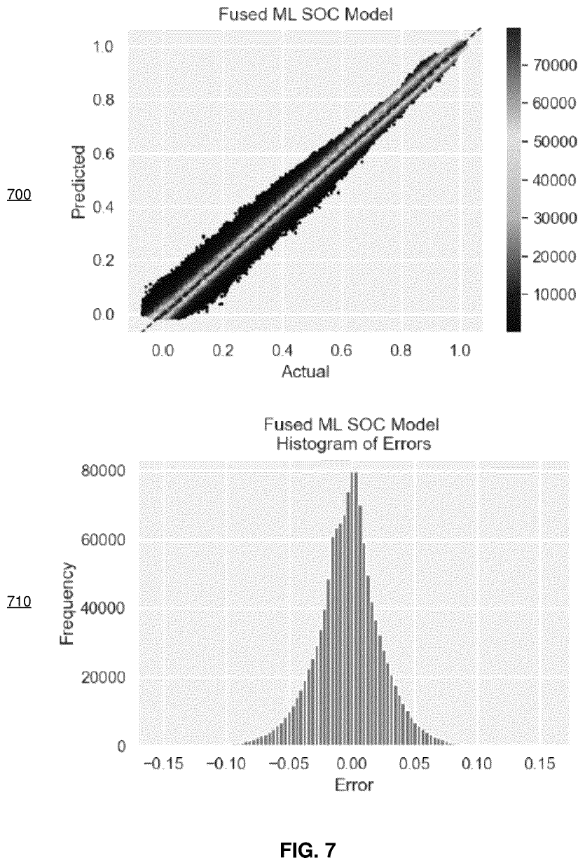

FIG. 7 is a plot diagram illustrating performance of fused machine-learning (ML) state-of-charge (SOC) models in accordance with the present disclosure. Shown in FIG. 7 are plots 700 and 710 that illustrate performance of an example fused ML-based SOC model.

In this regard, plots 700 and 710 may be similar to the plots 500 and 510—that is, with plot 700 including predicted SOC values (the y-axis) vs. actual SOC values (the x-axis), and plot 710 including the corresponding histogram of error figures of the values in plot 700. The plots 700 and 710 include data points illustrating performance of the example fused ML-based SOC model, however. The data corresponding to the fused ML SOC Model, as illustrated in plots 700 and 710, may be the results of three ML-based models fused at the output level by averaging their results. For example, the results shown in FIG. 7 illustrate that with use of the fused ML-based SOC model, MAE is 1.98%, RMSE is 2.63%, and r-squared value is 88.14%. The test dataset includes WLTP at room temperature, with a total number of, e.g., 1,273,762 data points.

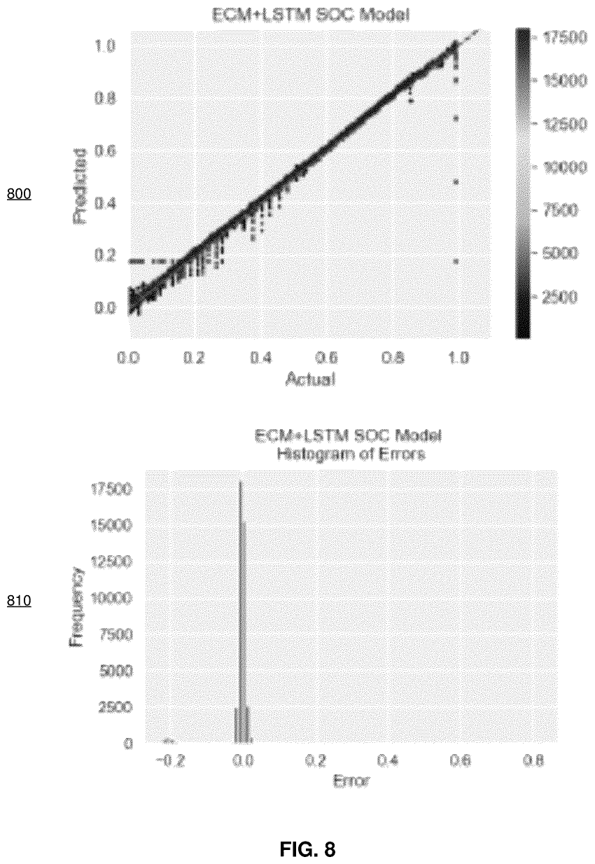

FIG. 8 is a plot diagram illustrating performance of a fused physics-based and machine learning based state-of-charge (SOC) model in accordance with the present disclosure. Shown in FIG. 8 are plots 800 and 810 that illustrate performance of an example enhanced physics-based SOC model.

In this regard, plots 800 and 810 may be similar to the plots 500 and 510—that is, with plot 800 including predicted SOC values (the y-axis) vs. actual SOC values (the x-axis), and plot 810 including the corresponding histogram of error figures of the values in plot 800. The plots 800 and 810 include data points illustrating performance of the example fused physics-based and ML based SOC model, however. In this regard, the data corresponding to the fused physics-based and ML based SOC model may be the results of results of an ECM model fused with a long short-term memory (LSTM) network. For example, the results shown in FIG. 8 illustrate that with use of the fused physics-based and ML based SOC model, MAE is 1.48%, RMSE is 4.33%, and r-squared value is 98.24%. The test dataset used includes three drive cycles from the WLTP dataset, with a total number of, e.g., 40,916 data points.

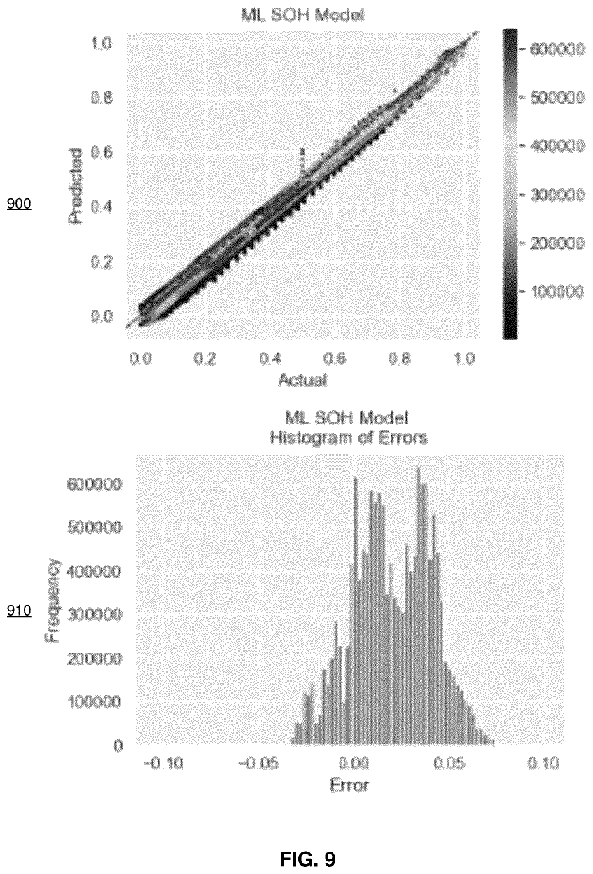

FIG. 9 is a plot diagram illustrating performance of a machine-learning (ML) state-of-health (SOH) model in accordance with the present disclosure. Shown in FIG. 9 are plots 900 and 910 that illustrate performance of an example fused ML-based SOH model.

In this regard, plot 900 includes predicted versus measured SOH values, to illustrate performance of the ML-based SOH model. In particular, the y-axis in plot 900 shows the SOH (values) predicted by the ML-based SOH model whereas the x-axis shows the actual SOH (values). Thus, each point in the plot represents the measured and calculated values for a single SOH point from the cycled cells in the dataset. The dashed lines represent instances where the modeled SOH equals the actual SOH. Plot 910 includes the corresponding histogram of error figures of the values in plot 900. The example ML SOH model whose performance is illustrated in FIG. 9 uses probabilistic features with inherent predictive capabilities which help inform the model of the expected state of the battery in the next time-step. Use of such ML-based SOH model yields enhanced performance. For example, the results shown in FIG. 9 illustrate that with use of the ML-based SOH, MAE is 2.41%, RMSE is 2.92%, and r-squared value is 99.06%. The test dataset includes three different standardized drive cycles, namely WLTP, US06, and FTP75, at 25 C and 45 C, with a total number of, e.g., 14,445,629 data points.

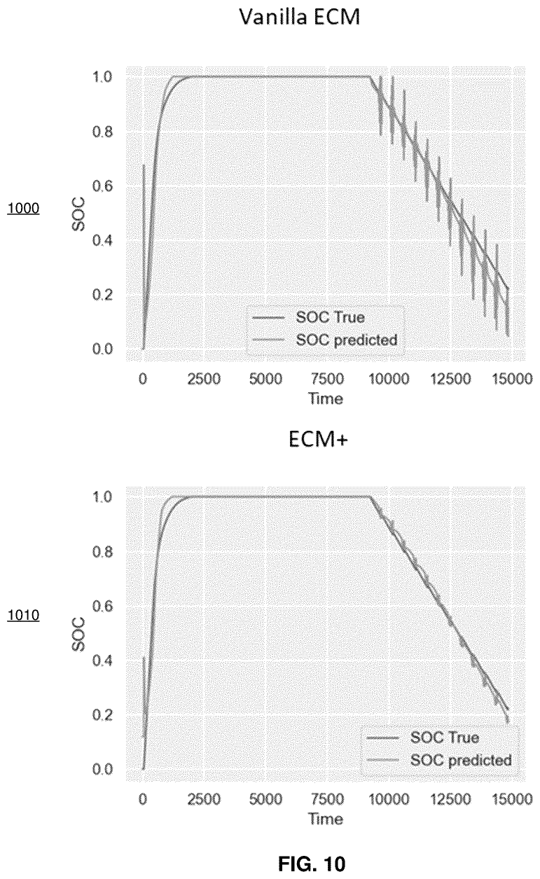

FIG. 10 is a plot diagram illustrating the difference in SOC prediction performance when using a plain conventional one-time constant Thevenin equivalent circuit model versus a one-time constant Thevenin equivalent circuit model equipped with momentum and overshoot attenuation. Shown in FIG. 10 are plots 1000 and 1010.

Plots 1000 and 1010 comprise data illustrating the difference in SOC prediction performance when using a plain conventional one-time constant Thevenin equivalent circuit model, depicted as “Vanilla ECM” compared to a one-time constant Thevenin equivalent circuit model equipped with momentum and overshoot attenuation depicted as “ECM+”. In this regard, plot 1000 includes the SOC truth values and predictions of a conventional ECM along a time axis of pulse data collected in a controlled lab experiment. The achieved MAE of the Vanilla ECM is 5.12%, RMSE is 8.23%, and r-squared value is 90.85%. Plot 1010 includes the SOC truth values and predictions of an ECM equipped with momentum and overshoot attenuation along a time axis of pulse data collected in a controlled lab experiment. The achieved MAE of the Vanilla ECM is 3.34%, RMSE is 5.40%, and r-squared value is 96.07%.

An example method, in accordance with the present disclosure, for managing a battery pack comprising one or more cells, comprises: assessing, using a plurality of models, one or both of a state-of-charge (SOC) and a state-of-health (SOH) of the one or more cells; and controlling the one or more cells based on the assessing, wherein the controlling comprises setting or modifying one or more operating parameters of at least one cell.

In an example embodiment, each of the one or more cells comprises a lithium-ion cell.

In an example embodiment, each of the one or more cells comprises a silicon-containing cell comprising a silicon-containing anode.

In an example embodiment, each of the one or more cells comprises a lithium iron phosphate-containing cell comprising a lithium iron phosphate-containing cathode.

In an example embodiment, at least one of the plurality of models is a physics-based model associated with at least one cell, and wherein the physics-based model comprises information relating to modeling of one or more physical phenomena as factors that affect at least one parameter or characteristic of the at least one cell.

In an example embodiment, the physics-based model is comprised of an equivalent circuit model equipped with performance enhancing algorithms such as overshoot attenuation, settling-time adjustments, Kalman filters and their extensions, and/or prediction smoothing formulas such as momentum, moving averages, and/or signal processing filters.

In an example embodiment, at least one of the plurality of models is a machine-learning (ML) model. The machine-learning (ML) model may be dependent on various types of features, such as, directly observed data, partitions of observed data, different mathematical interpretations or manipulations of observed data, instantaneously observed data, locally characterized observed data, historically characterized observed data, outputs of other models, internal states of physics-based models, probabilistic features, fingerprint features indicative of battery usage modes and profiles, etc.

In an example embodiment, the method further comprises training the machine-learning (ML) model using one or more machine-learning (ML) algorithms.

In an example embodiment, the method further comprises training at least one model.

In an example embodiment, the method further comprises training the at least one model using training data.

In an example embodiment, the method further comprises configuring at least one model using data related to or acquired during formation of at least one lithium-ion cell or fabrication of one or more components of at least one lithium-ion cell, and/or data related to or acquired during operation of at least one lithium-ion cell.

In an example embodiment, the method further comprises fusing at least some of the plurality of models to generate a fusion model, and assessing one or both of the state-of-charge (SOC) and the state-of-health (SOH) based on the fusion model.

In an example embodiment, the method further comprises fusing the at least some of the plurality of models at observation level, at feature level, and/or at decision level.

In an example embodiment, the fusing comprises averaging outputs, uniformly or in a weighted sense, of at least some of the plurality of models.

In an example embodiment, the fusion model comprises a separate machine learning (ML) based model, and wherein the fusing comprises feeding outputs of at least some of the plurality of models into the separate machine learning (ML) based model.

In an example embodiment, the method further comprises selecting at least some of the plurality of models from the plurality of models. The selection of the models may be done using a switcher according to directly observed battery data by the BMS and/or the features extracted from the observed battery data by the BMS.

In an example embodiment, the controlling is configured to equilibrate the state-of-charge (SOC) of the one or more cells or to modify a state-of-charge (SOC) of at least one cell so that the one or more cells have a balanced state-of-charge (SOC).

In an example embodiment, the controlling is configured to equilibrate the state-of-health (SOH) of the one or more cells or to modify a state-of-health (SOH) of at least one cell so that the one or more cells have a uniform state-of-health (SOH).

An example system, in accordance with the present disclosure, comprises one or more circuits configured to assess, using a plurality of models, one or both of a state-of-charge (SOC) and a state-of-health (SOH) of one or more cells; and control, based on the assessing, the one or more cells, wherein the controlling comprises setting or modifying one or more operating parameters of at least one cell.

In an example embodiment, each of the one or more cells comprises a lithium-ion cell.

In an example embodiment, each of the one or more cells comprises a silicon-containing cell comprising a silicon-containing anode.

In an example embodiment, each of the one or more cells comprises a lithium iron phosphate-containing cell comprising a lithium iron phosphate-containing cathode.

In an example embodiment, at least one of the plurality of models is a physics-based model associated with at least one cell, and wherein the physics-based model comprises information relating to modeling of one or more physical phenomena as factors that affect at least one parameter or characteristic of the at least one cell.

In an example embodiment, the one or more circuits are configured to train at least one model.

In an example embodiment, at least one of the plurality of models is a machine-learning (ML) model, and wherein the one or more circuits are configured to train the machine-learning (ML) model using one or more machine-learning (ML) algorithms.

In an example embodiment, the one or more circuits are configured to configure at least one model using data related to or acquired during formation of at least one cell or fabrication of one or more components of at least one cell, and/or data related to or acquired during operation of at least one cell.

In an example embodiment, the one or more circuits are configured to fuse at least some of the plurality of models to generate a fusion model, and assess one or both of the state-of-charge (SOC) and the state-of-health (SOH) based on the fusion model.

In an example embodiment, the one or more circuits are configured to fuse at least some of the plurality of models at observation level, at feature level, and/or at decision level.

In an example embodiment, the one or more circuits are configured to, when fusing at least some of the plurality of models, average outputs of all of at least some of the plurality of models.

In an example embodiment, the fusion model comprises a separate machine learning (ML) based model, and wherein the one or more circuits are configured to, when fusing the at least some of the plurality of models, feed outputs of at least some of the plurality of models into the separate machine learning (ML) based model.

In an example embodiment, the one or more circuits are configured to select at least some of the plurality of models. The selection of the models is done using a switcher according to directly observed battery data by the BMS and/or the features extracted from the observed battery data by the BMS.

In an example embodiment, the one or more circuits are configured to, when controlling the one or more cells, equilibrate the state-of-charge (SOC) of the one or more cells or to modify a state-of-charge (SOC) of at least one cell so that the one or more cells have a balanced state-of-charge (SOC).

In an example embodiment, the one or more circuits are configured to, when controlling the one or more cells, equilibrate the state-of-health (SOH) of the one or more cells or to modify a state-of-health (SOH) of at least one cell so that the one or more cells have a uniform state-of-health (SOH).

As utilized herein, “and/or” means any one or more of the items in the list joined by “and/or”. As an example, “x and/or y” means any element of the three-element set {(x), (y), (x, y)}. In other words, “x and/or y” means “one or both of x and y.” As another example, “x, y, and/or z” means any element of the seven-element set {(x), (y), (z), (x, y), (x, z), (y, z), (x, y, z)}. In other words, “x, y and/or z” means “one or more of x, y, and z.” As utilized herein, the term “exemplary” means serving as a non-limiting example, instance, or illustration. As utilized herein, the terms “for example” and “e.g.” set off lists of one or more non-limiting examples, instances, or illustrations.

As utilized herein the terms “circuits” and “circuitry” refer to physical electronic components (e.g., hardware), and any software and/or firmware (“code”) that may configure the hardware, be executed by the hardware, and or otherwise be associated with the hardware. As used herein, for example, a particular processor and memory (e.g., a volatile or non-volatile memory device, a general computer-readable medium, etc.) may comprise a first “circuit” when executing a first one or more lines of code and may comprise a second “circuit” when executing a second one or more lines of code. Additionally, a circuit may comprise analog and/or digital circuitry. Such circuitry may, for example, operate on analog and/or digital signals. It should be understood that a circuit may be in a single device or chip, on a single motherboard, in a single chassis, in a plurality of enclosures at a single geographical location, in a plurality of enclosures distributed over a plurality of geographical locations, etc. Similarly, the term “module” may, for example, refer to a physical electronic components (e.g., hardware) and any software and/or firmware (“code”) that may configure the hardware, be executed by the hardware, and or otherwise be associated with the hardware.

As utilized herein, circuitry or module is “operable” to perform a function whenever the circuitry or module comprises the necessary hardware and code (if any is necessary) to perform the function, regardless of whether performance of the function is disabled or not enabled (e.g., by a user-configurable setting, factory trim, etc.).

Other embodiments of the invention may provide a non-transitory computer readable medium and/or storage medium, and/or a non-transitory machine readable medium and/or storage medium, having stored thereon, a machine code and/or a computer program having at least one code section executable by a machine and/or a computer, thereby causing the machine and/or computer to perform the processes as described herein.

Accordingly, various embodiments in accordance with the present invention may be realized in hardware, software, or a combination of hardware and software. The present invention may be realized in a centralized fashion in at least one computing system, or in a distributed fashion where different elements are spread across several interconnected computing systems. Any kind of computing system or other apparatus adapted for carrying out the methods described herein is suited. A typical combination of hardware and software may be a general-purpose computing system with a program or other code that, when being loaded and executed, controls the computing system such that it carries out the methods described herein. Another typical implementation may comprise an application specific integrated circuit or chip.

Various embodiments in accordance with the present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A method for managing a battery pack comprising one or more cells, the method comprising:
assessing, using a plurality of models, one or both of a state-of-charge (SOC) and a state-of-health (SOH) of the one or more cells; and
controlling the one or more cells based on the assessing, wherein the controlling comprises setting or modifying one or more operating parameters of at least one cell.

2. The method of claim 1, wherein at least one of the plurality of models is a physics-based model associated with at least one cell, and wherein the physics-based model comprises information relating to modeling of one or more physical phenomena as factors that affect at least one parameter or characteristic of the at least one cell.

3. The method of claim 2, wherein the physics-based model is comprised of an equivalent circuit model equipped with performance enhancing algorithms such as overshoot attenuation, settling-time adjustments, Kalman filters and their extensions, and/or prediction smoothing formulas such as momentum, moving averages, and/or signal processing filters.

4. The method of claim 1, wherein at least one of the plurality of models is a machine-learning (ML) model.

5. The method of claim 4, further comprising training the machine-learning (ML) model using one or more machine-learning (ML) algorithms.

6. The method of claim 1, further comprising training at least one model.

7. The method of claim 6, further comprising training the at least one model using training data.

8. The method of claim 1, further comprising configuring at least one model using data related to or acquired during formation of at least one lithium-ion cell or fabrication of one or more components of at least one lithium-ion cell, and/or data related to or acquired during operation of at least one lithium-ion cell.

9. The method of claim 1, further comprising fusing at least some of the plurality of models to generate a fusion model, and assessing one or both of the state-of-charge (SOC) and the state-of-health (SOH) based on the fusion model.

10. The method of claim 9, further comprising fusing the at least some of the plurality of models at observation level, at feature level, and/or at decision level.

11. The method of claim 9, wherein the fusing comprises averaging outputs, uniformly or in a weighted sense, of at least some of the plurality of models.

12. The method of claim 9, wherein the fusion model comprises a separate machine learning (ML) based model, and wherein the fusing comprises feeding outputs of at least some of the plurality of models into the separate machine learning (ML) based model.

13. The method of claim 9, further comprising selecting at least some of the plurality of models from the plurality of models.

14. The method of claim 1, wherein the controlling is configured to equilibrate the state-of-charge (SOC) of the one or more cells or to modify a state-of-charge (SOC) of at least one cell so that the one or more cells have a balanced state-of-charge (SOC).

15. The method of claim 1, wherein the controlling is configured to equilibrate the state-of-health (SOH) of the one or more cells or to modify a state-of-health (SOH) of at least one cell so that the one or more cells have a uniform state-of-health (SOH).

16. A system comprising:
one or more circuits configured to:
assess, using a plurality of models, one or both of a state-of-charge (SOC) and a state-of-health (SOH) of one or more cells; and
control, based on the assessing, the one or more cells, wherein the controlling comprises setting or modifying one or more operating parameters of at least one cell.

17. The system of claim 16, wherein each of the one or more cells comprises a lithium-ion cell.

18. The system of claim 16, wherein each of the one or more cells comprises a silicon-containing cell comprising a silicon-containing anode.

19. The system of claim 16, wherein each of the one or more cells comprises a lithium iron phosphate-containing cell comprising a lithium iron phosphate-containing cathode.

20. The system of claim 16, wherein at least one of the plurality of models is a physics-based model associated with at least one cell, and wherein the physics-based model comprises information relating to modeling of one or more physical phenomena as factors that affect at least one parameter or characteristic of the at least one cell.

21. The system of claim 16, wherein the one or more circuits are configured to train at least one model.

22. The system of claim 21, wherein at least one of the plurality of models is a machine-learning (ML) model, and wherein the one or more circuits are configured to train the machine-learning (ML) model using one or more machine-learning (ML) algorithms.

23. The system of claim 16, wherein the one or more circuits are configured to configure at least one model using data related to or acquired during formation of at least one cell or fabrication of one or more components of at least one cell, and/or data related to or acquired during operation of at least one cell.

24. The system of claim 16, wherein the one or more circuits are configured to fuse at least some of the plurality of models to generate a fusion model, and assess one or both of the state-of-charge (SOC) and the state-of-health (SOH) based on the fusion model.

25. The system of claim 24, wherein the one or more circuits are configured to fuse at least some of the plurality of models at observation level, at feature level, and/or at decision level.

26. The system of claim 24, wherein the one or more circuits are configured to, when fusing at least some of the plurality of models, average outputs of all of at least some of the plurality of models.

27. The system of claim 24, wherein the fusion model comprises a separate machine learning (ML) based model, and wherein the one or more circuits are configured to, when fusing the at least some of the plurality of models, feed outputs of at least some of the plurality of models into the separate machine learning (ML) based model.

28. The system of claim 24, wherein the one or more circuits are configured to select at least some of the plurality of models.

29. The system of claim 16, wherein the one or more circuits are configured to, when controlling the one or more cells, equilibrate the state-of-charge (SOC) of the one or more cells or to modify a state-of-charge (SOC) of at least one cell so that the one or more cells have a balanced state-of-charge (SOC).

30. The system of claim 16, wherein the one or more circuits are configured to, when controlling the one or more cells, equilibrate the state-of-health (SOH) of the one or more cells or to modify a state-of-health (SOH) of at least one cell so that the one or more cells have a uniform state-of-health (SOH).
